(19) United States
(12) Patent Application Publication
(10) Pub. No.: US 2009/0213288 A1
(43) Pub. Date: Aug. 27, 2009

(54) ACITVE DEVICE ARRAY SUBSTRATE AND LIQUID CRYSTAL DISPLAY PANEL

(75) Inventors: Shih-Chin Chen, Taoyuan County (TW); Meng-Chieh Tai, Yilan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/235,621

(22) Filed: Sep. 23, 2008

(30) Foreign Application Priority Data
Feb. 25, 2008 (TW) 97106515

(51) Int. Cl. G02F 1/136; H01L 27/12

(52) U.S. Cl. 349/43; 257/48; 257/E27.112

(57) ABSTRACT

An active device array substrate, having a display region and a peripheral circuit region outside of the display region, is provided. The peripheral circuit region has a terminal region and a narrow-edge region between the terminal region and the display region. The active device array substrate includes a pixel array, multiple electrode lines and a testing device. The pixel array is disposed in the display region. The electrode lines are disposed in the peripheral circuit region and electrically connected with the pixel array. The testing device is disposed in the narrow-edge region for inspecting the active device array substrate. After the inspection, an additional cutting process is needless for removing the testing device, so that the process cost is reduced. A liquid crystal display panel with the above active device array substrate is also provided.

### CROSS-REFERENCE TO RELATED APPLICATION

This application claims the priority benefit of Taiwan application serial no. 97106515, filed on Feb. 25, 2008. The entirety of the above-mentioned patent application is hereby incorporated by reference herein and made a part of this specification.

### BACKGROUND OF THE INVENTION

1. Field of the Invention

The present invention relates to an array substrate and a display panel, and in particular, to an active device array substrate having a testing device and to a liquid crystal display panel having the active device array substrate.

2. Description of Related Art

The thin film transistor liquid crystal display (TFT-LCD) has become the mainstream among various flat panel displays for its superior characteristics such as high resolution, good space usage, low power consumption and free of radiation. Particularly, when fabricating the TFT-LCD, the electrode line has to be tested to ensure that the TFT-LCD can function normally.

FIG. 1A is a schematic view of a conventional TFT-LCD. Referring to FIG. 1A, a TFT-LCD 100 has a display region 110 and a peripheral circuit region 120, wherein the display region 110 has a plurality of electrode lines 130 disposed thereon. A plurality of driving circuits 140 is disposed on the peripheral circuit region 120 to drive the electrode lines 130. Shorting bars 150 are electrically coupled to the electrode lines 130. By utilizing the additionally disposed shorting bars 150, every two or every three electrode lines 130 are electrically connected together, and thereby a number of testing probes (not shown) can be reduced. Moreover, by inputting a signal to the electrode lines 130 through the shorting bars 150, the TFT-LCD 100 can be tested.

However, after the inspection on the TFT-LCD is completed, an additional cutting process has to be performed to remove the additional shorting bars 150. Therefore, process time and a process cost are increased.

FIG. 1B is a schematic view of a conventional TFT-LCD. Referring to FIG. 1B, the shorting bars 152 are disposed on a peripheral circuit region 122 of a TFT-LCD 102, and are electrically coupled to the electrode lines 132. Similarly, by inputting a signal to the electrode lines 132 through the shorting bars 152, the TFT-LCD 102 can be tested.

After the inspection on the TFT-LCD 102 is completed, a laser cutting process has to be performed to cut off the electrical connection between the shorting bars 152 and the TFT-LCD 102. Thus, the process time and the process cost are increased.

In order to avoid the additional cutting process or the laser cutting process, another conventional TFT-LCD is provided. FIG. 2 is a schematic view of still another conventional TFT-LCD. Referring to FIG. 2, a TFT-LCD 104 has a display region 170 and a peripheral circuit region 170a. The testing device 160 is disposed in the peripheral circuit region 170a and is in an opposite side of a gate driving circuit 172 or a source driving circuit 174.

Switch elements 168 are disposed in the testing device 160. The switch elements 168 are disposed in the conjunction between each scan line 162 and a testing line 166, and disposed in the conjunction between each data line 164 and the testing line 166′. In the process of inspection, the switch elements 168 are switched on, so that the scan lines 162 and the data lines 164 are respectively connected to the respect testing and 166′. After the inspection is completed, the switch elements 168 are switched off, and thereby the scan lines 162 and the data lines 164 can be driven normally.

However, the TFT-LCD 104 can only be applied to designing a single-side gate/source driving circuit (1G1S) and can not be applied to designing a both-side gate/source driving circuit (2G2S). Although the testing device 160 can be disposed outside of the gate driving circuit 172 or the source driving circuit 174, the area of the entire peripheral circuit region is increased, and thereby an incompatible problem among panels occurs.

### SUMMARY OF THE INVENTION

In solution, the present invention is directed to an active device array substrate having a testing device. After inspection, no additional cutting process is required, and in particular, an area of the peripheral circuit region is prevented from increasing. Therefore, the compatibility of the panel is superior.

The present invention is further directed to a liquid crystal display panel having the above-mentioned active device array substrate.

As embodied and broadly discussed herein, the present invention provides an active device array substrate. The active device array substrate has a display region, a peripheral circuit region outside of the display region, wherein the peripheral circuit region has a terminal region and a narrow-edge region between the terminal region and the display region. The active device array substrate includes a pixel array, a plurality of electrode lines and a testing device. The pixel array is disposed in the display region. A plurality of electrode lines disposed in the peripheral circuit region and electrically connected with the pixel array. The testing device is disposed in the narrow-edge region for inspecting the active device array substrate.

The present invention also provides a liquid crystal display panel, including the active device array substrate, a color filter substrate, and a liquid crystal layer. The color filter substrate is disposed in an opposite side of the active device array substrate, and the liquid crystal layer is disposed between the color filter substrate and the active device array substrate.

According to one embodiment of the present invention, the testing device includes a plurality of testing lines, a plurality of switch lines, a plurality of switch elements and a testing switch line. The testing lines are perpendicular to the electrode lines. The testing lines are electrically connected with the electrode lines respectively. The switch lines are parallel to the electrode lines. Each of the switch lines is disposed between adjacent two electrode lines. A plurality of switch elements is respectively disposed on each of the switch lines. Each of the testing lines is electrically connected with each of the electrode lines through each of the switch elements, and an electrode connection point is between each of the electrode lines and each of the testing lines. The testing switch line is electrically connected with the switch lines in order to switch on/off the switch elements.

According to one embodiment of the present invention, the electrode connection point is, for example, a contact window, so that the testing line is electrically connected with the corresponding electrode line through the contact window.

According to one embodiment of the present invention, the switch element includes at least one thin film transistor, wherein the thin film transistor includes a gate, a first source/drain and a second source/drain. The gate is electrically connected with the corresponding switch line. The first source/drain is electrically connected with the corresponding electrode line. The second source/drain is electrically connected with the corresponding testing line.

According to one embodiment of the present invention, the switch element includes a thin film transistor and a diode, wherein the diode is electrically connected between the testing line and the switch line.

According to one embodiment of the present invention, the active device array substrate further comprises at least one shorting bar disposed in the peripheral circuit region and electrically connected with the testing lines.

According to one embodiment of the present invention, the electrode lines are scan lines or data lines.

According to one embodiment of the present invention, the active device array substrate or the liquid crystal display panel further comprises at least one driver pad connected with the electrode lines. The driver pad is suitable for transmitting a driving signal provided by a driving circuit. Further, the active device array substrate or the liquid crystal display panel further includes at least one panel detecting pad disposed besides the corresponding driver pad, wherein the panel detecting pads with the same driving signal are electrically connected together.

In summary, according to the present invention, by adopting the testing device in the active device array device and the liquid crystal display panel, and by disposing the testing device in the narrow-edge region of the peripheral circuit region, the area of the peripheral circuit region of the panel is prevented from increasing. Moreover, the present invention can be applied to designing a both-side gate/source driving circuit (2G2S). In addition, when the display is normal, the switch elements of the testing device are in a high resistance state (close to a cut-off state), so that the cutting process for cutting off an electrical connection between the testing device and the electrode lines is omitted after the implementation of the inspection. Further, the switch elements are disposed on the switch lines separated from the electrode lines, and thereby, when the display is normal, the switch elements in a switched-off state do not prevent the transmission of the signal in the electrode lines. Moreover, the active device array substrate can prevent the substrate from electric static discharge (ESD) damage.

To make the above and other objectives, features, and advantages of the present invention more comprehensible, several embodiments accompanied with figures are detailed as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic view of a conventional thin film transistor liquid crystal display.

FIG. 1B is a schematic view of another conventional thin film transistor liquid crystal display.

FIG. 2 is a schematic view of still another conventional thin film transistor liquid crystal display.

FIG. 3 is a schematic view illustrating an active device array substrate according to the first embodiment of the present invention.

FIG. 4 is a schematic view illustrating a testing device according to one embodiment of the present invention.

FIG. 5 is a schematic view illustrating the active device array substrate according to the second embodiment of the present invention.

FIG. 6 is a schematic view illustrating another testing device according to one embodiment of the present invention.

FIG. 7 is a schematic view illustrating a liquid crystal display panel according to one embodiment of the present invention.

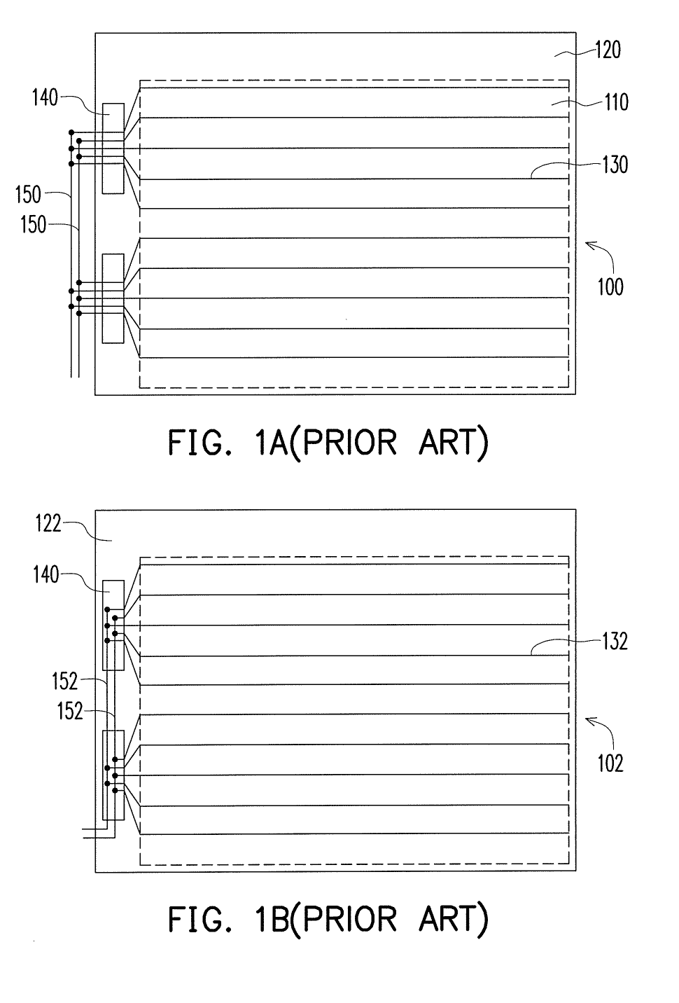

### DESCRIPTION OF EMBODIMENTS

Hereinafter, a testing method for a single-side source driving circuit is taken as an example to describe the embodiments of the present invention. However, the present invention can also be applied to the inspection of a single-side gate driving circuit and a both-side gate/source driving circuit (2G2S). The arrangement of the driving circuit is not limited to the present invention.

### First Embodiment

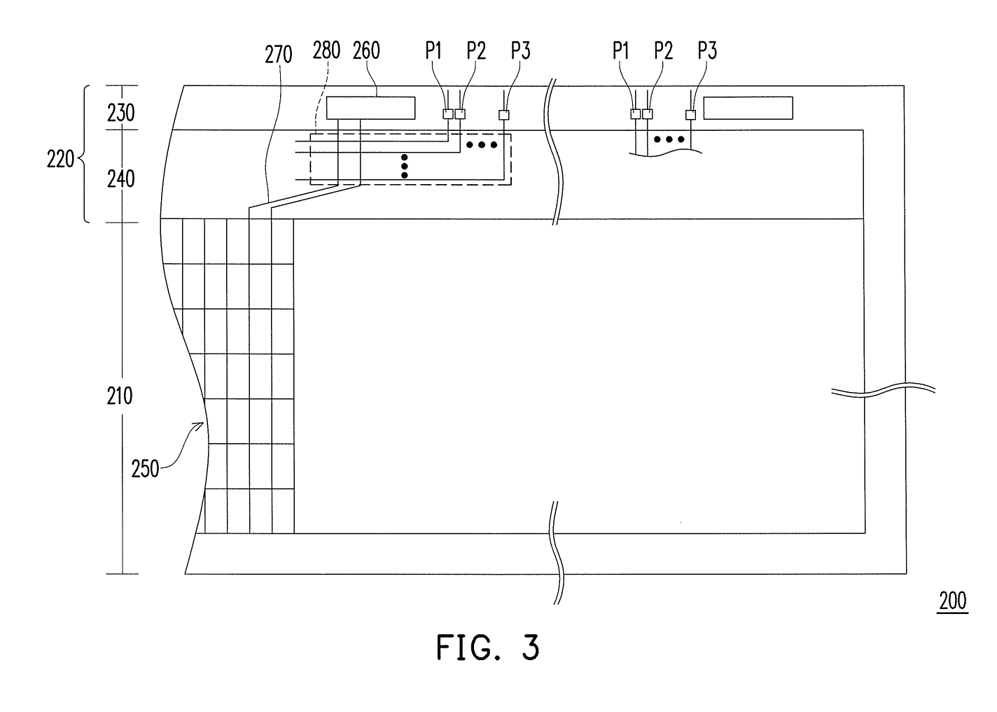

FIG. 3 is a schematic view illustrating an active device array substrate according to the first embodiment of the present invention. In the present embodiment, only one portion of an active device array substrate 200 is shown, and a single-side source driving circuit is taken as an example. Referring to FIG. 3, the active device array substrate 200 has a display region 210 and a peripheral circuit region 220 outside of the display region 210, wherein the peripheral circuit region 220 has a terminal region 230 and a narrow-edge region 240 between the terminal region 230 and the display region 210. The active device array substrate 200 includes a pixel array 250, a plurality of electrode lines 270 and a testing device 280. According to the present embodiment, the active device array substrate 200 further comprises at least one driver pad 260, wherein the driver pad 260 is connected with the electrode line 270, and the driver pad 260 is suitable for transmitting a driving signal provided by a driving circuit (not shown).

Referring to FIG. 3, the pixel array 250 is disposed in the display region 210, and the driver pad 260 is disposed in the terminal region 230 of the peripheral circuit region 220. A plurality of electrode lines 270 is disposed in the peripheral circuit region 220 and electrically connected with the pixel array 250. The electrode line 270 is driven by the driving circuit through the driver pad 260. The testing devices 280 are disposed in the narrow-edge region 240 for inspecting the active device array substrate 200, wherein the electrode line 270 can be a scan line or a data line.

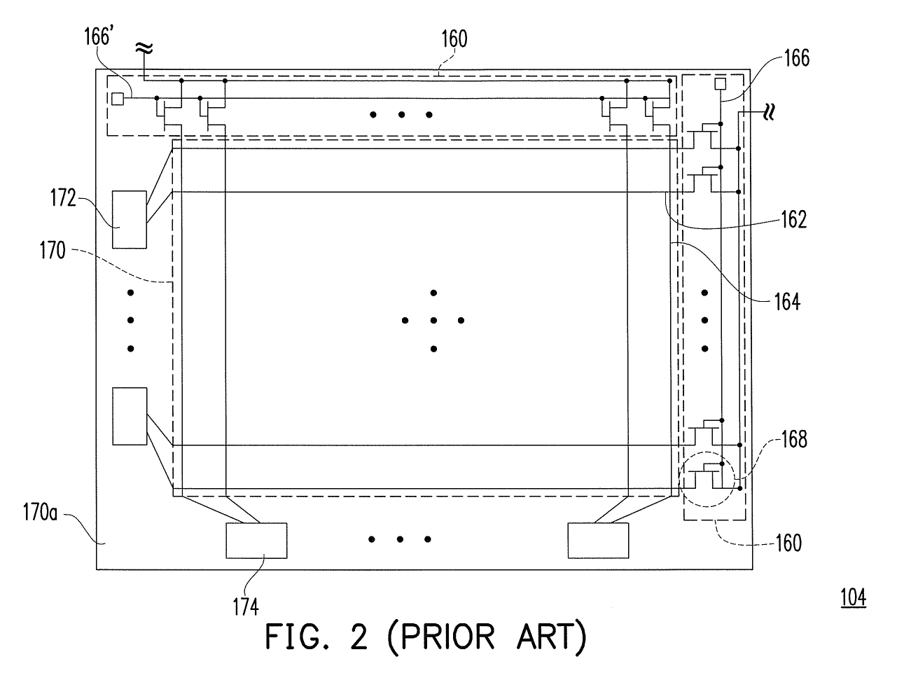

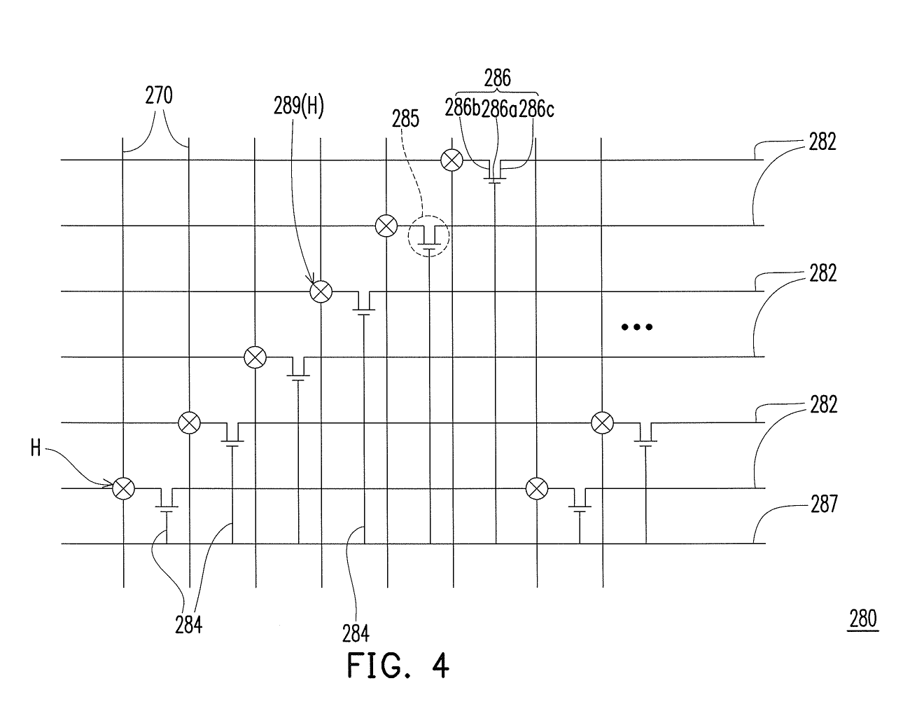

It should be noted that the conventional testing device 160 (as shown in FIG. 2) can only be disposed in an opposite side of the gate driving circuit 172 or the source driving circuit 174. However, according to the present embodiment, the testing device 280 is disposed in the narrow-edge region 240, and thus the area of the peripheral circuit region 220 of the panel is prevented from increasing. Moreover, the way of disposing the testing device 280 can be utilized in both-side gate/source driving circuit arrangement or in any kind driving circuit arrangement, and particularly can be used in a large-sized liquid crystal display panel requiring larger driving current. In addition, by utilizing the testing device 280 having a switch element 285 (shown in FIG. 4), a cutting process for cutting off an electrical connection between the testing device 280 and the electrode line 270 can be omitted, and thereby process time and a process cost are reduced.

FIG. 4 is a schematic view illustrating a testing device according to one embodiment of the present invention. Referring to FIG. 4, the testing device 280 may include a plurality of testing lines 282, a plurality of switch lines 284, a plurality of switch elements 285, and a testing switch line 287. As shown in FIG. 4, the testing lines 282 are perpendicular to the electrode lines 270, and each of the testing lines 282 is electrically connected with the electrode lines 270 respectively. The switch lines 284 are parallel to the electrode lines 270. Each of the switch lines 284 is disposed between adjacent two electrode lines 270. The switch elements 285 are respectively disposed on each of the switch lines 284. Each of the testing lines 282 is electrically connected with each of the electrode lines 270 through each of the switch elements 285, and an electrode connection point 289 is between each of the electrode lines 270 and each of the testing lines 282. The testing switch line 287 is electrically connected with the switch lines 284 in order to switch on/off the switch elements 285.

The electrode lines 270 and testing lines 282 are different film layers. The electrode lines 270 are, for example, a first metal layer (metal 1), and the testing lines 282 are, for example, a second metal layer (metal 2). However, the film layers used to fabricate the electrode lines 270, the testing lines 282, the switch lines 284 and the testing switch line 287 are not limited to the present invention. The present invention can incorporate the metal 1, the metal 2 and a pixel electrode layer into a circuit layout. Accordingly, a contact window H is utilized to electrically connect the both layers to each other. That is to say, the electrode connection point 289 is, for example, the contact window H, and thereby the testing lines 282 are electrically connected with the corresponding electrode lines 270 through the contact window H. Therefore, the electrode lines 270 can be inspected through the testing lines 282.

Referring to FIG. 4, the testing lines 282 and the electrode lines 270 are electrically connected through the switch element 285. Each of the switch elements 285 includes at least one thin film transistor 286. The thin film transistor 286 has a gate 286a, a first source/drain 286b, and a second source/drain 286c.

In the thin film transistor 286, the gate 286a is electrically connected with the corresponding switch line 284. The first source/drain 286b is electrically connected with the corresponding electrode line 270. The second source/drain 286c is electrically connected with the corresponding testing line 282. Particularly, the first source/drain 286b is electrically connected with the corresponding electrode line 270 through the contact window H. In addition, in other embodiments, the switch element 285 can be constituted by multiple thin film transistors 286 or other active elements. The present invention is not intended to limit the switch element 285 to include only one thin film transistor.

It should be noted that, the switch elements 285 are respectively disposed on each of the switch lines 284, but not directly disposed on the electrode lines 270. During inspection, an inputted voltage is provided from the testing switch line 287 to the switch lines 284. Therefore, each of the switch elements 285 is turned on by the inputted voltage so that the electrode lines 270 can be inspected through the testing lines 282. After the inspection is completed, the switch elements 285 are switched off to disconnect the electrode lines 270 from the testing lines 282.

Therefore, when performing the display, each of the electrode lines 270 can function normally and the electrode lines 270 are prevented from being electrically connected through the testing lines 282. Further, the switch elements 285 are separated from the electrode lines 270 and disposed on the switch lines 284, and thereby, when the display is in normal operation, the switch elements 285 in a switched-off state do not obstruct the transmission of the signal in the electrode lines 270. The above-mentioned technical effect can not be achieved by using a conventional thin film transistor liquid crystal display 104 as shown in FIG. 2, which is explained hereinafter.

Referring to FIGS. 2 and 3 at the same time, in the traditional thin film transistor liquid crystal display 104, a switch element 168 is directly disposed on a scan line 162 or a data line 164, so that the switch element 168 (a testing device 160) can not be disposed between a gate driving circuit 172 and a display region 170, and can not be disposed between a source driving circuit 174 and the display region 170.

More specifically, assuming that the testing device 160 is disposed between the gate driving circuit 172 and the display region 170 (or between the source driving circuit 174 and the display region 170), the thin film transistor liquid crystal display 104 can be inspected when the switch element 168 is electrically connected.

However, when it is intended to enter a display state, the switch element 168 has to be switched off. Thus, because the switch element 168 is switched off, the signal outputted from the gate driving circuit 172 or source driving circuit 174 is obstructed from being transmitted to the display region 170, and thereby an image can not be displayed.

### Second Embodiment

In addition, electrostatic accumulation often occurs in the process of fabricating the active device array substrate 200. When the accumulation of static charges exceeds a certain amount, an electric static discharge (ESD) occurs, and thereby the circuit on the active device array substrate 200 is damaged. In order to prevent the above-mentioned ESD damage, the present invention provides another active device array substrate.

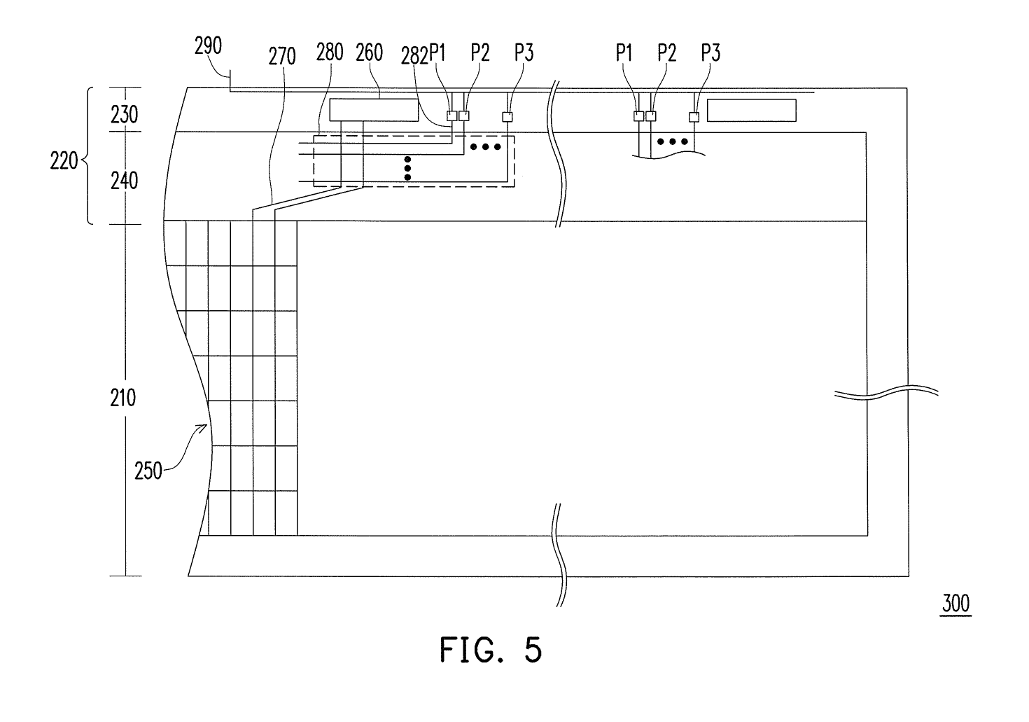

FIG. 5 is a schematic view illustrating the active device array substrate according to the second embodiment of the present invention.

Referring to FIG. 5, an active device array substrate 300 is similar to the first embodiment. The active device array substrate 300 further includes at least one shorting bar 290 disposed in the peripheral circuit region 220. The shorting bar 290 is electrically connected with the testing lines 282 and can be used to protect the circuit by discharging the static charges, and thereby the above-mentioned ESD damage can be reduced.

Particularly, the shorting bar 290 can also be not required, which is achieved by directly making all panel detecting pads with the same signal electrically connected together (not shown). The panel detecting pad is disposed besides the corresponding driver pad 260. As shown in FIGS. 3 and 5, the active device array substrate 300 further comprises at least one panel detecting pad P1, P2 or P3 disposed besides the corresponding driver pad 260, wherein the panel detecting pads P1 with the same driving signal are electrically connected together.

Please referring to FIG. 3, when the shorting bar 290 is omitted, P1 may be electrically connected to P1 (herein, merely two P1 are illustrated), P2 may be electrically connected to P2 (herein, merely two P2 are illustrated), and P3 may be electrically connected to P3 (herein, merely two P3 are illustrated). Or other not-illustrated panel detecting pads having the same driving signal may be electrically connected to one another. Therefore, the accumulated static charges can also be discharged through the connected panel detecting pads, such as P1-P1- . . . -P1; P2-P2- . . . P2 and P3-P3- . . . -P3 , and ESD effect can be effectively achieved.

Furthermore, the present invention further provides a testing device 380 in order to prevent the switch elements 285 in the testing device 280 from being damaged by the accumulation of the static charges and thereby to prevent a shortage problem of the electrode lines 270.

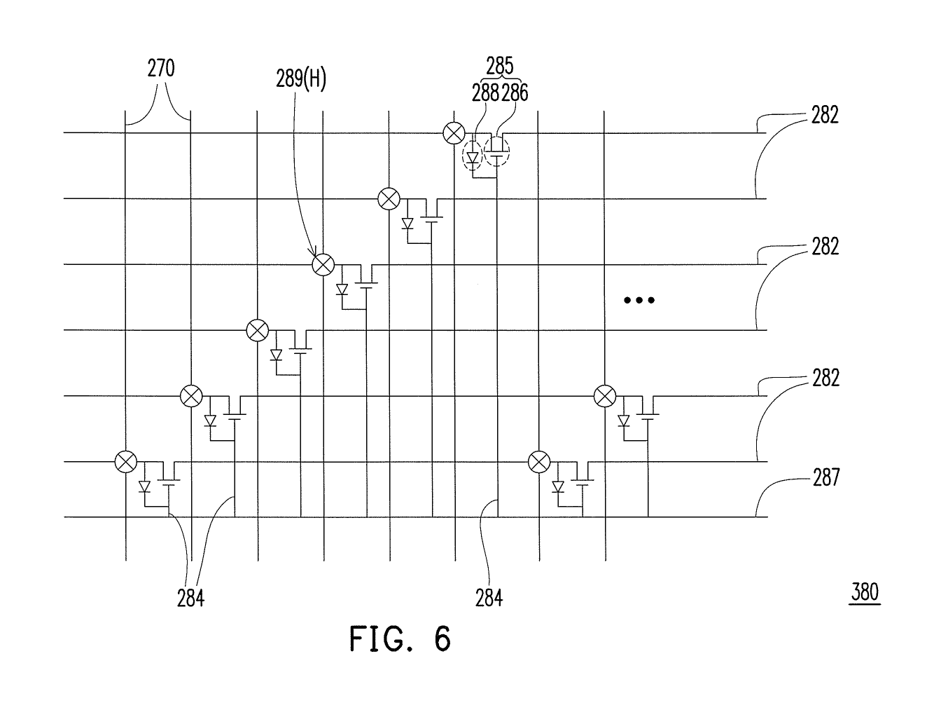

FIG. 6 is a schematic view illustrating another testing device according to one embodiment of the present invention. Referring to FIG. 6, the testing device 380 is similar to the testing device 280 of the first embodiment. The difference between the testing device 380 and the testing device 280 lies in that the switch elements 285 further has a diode 288 electrically connected between the testing lines 282 and the switch lines 284.

The diode 288 and the thin film transistor 286 are connected in parallel. Therefore, when a current of the electrode lines 270 is overly large, electric charges flow through the corresponding diode and not through the thin film transistor 286. Thus, the electric charges are transmitted to the corresponding switch line 284, and then the electric charges converge in the testing switch line 287 and are discharged. Thereby, the thin film transistor 286 is prevented from being damaged by an overly-large current, so that an abnormal display caused by a signal shortage between the electrode lines 270 is prevented.

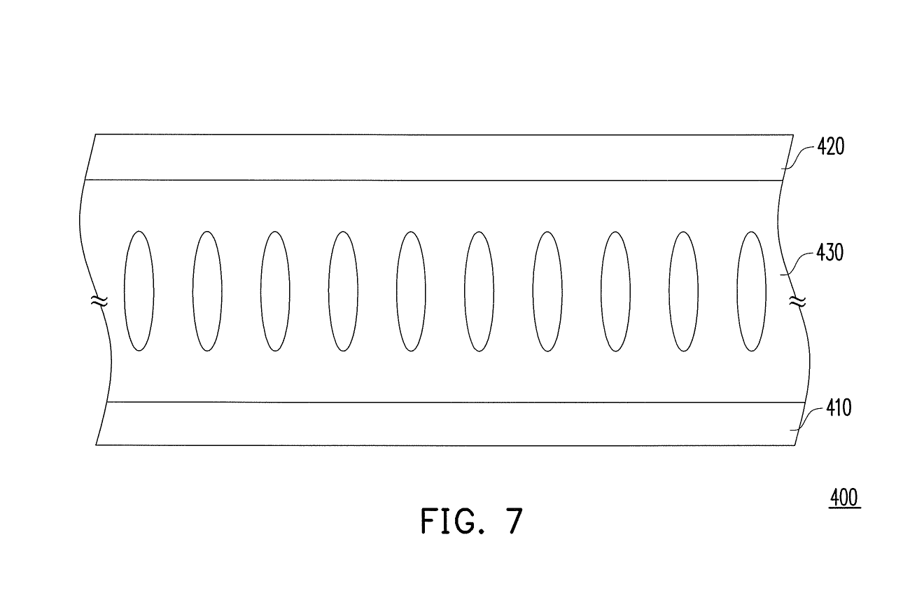

FIG. 7 is a schematic view illustrating a liquid crystal display panel according to one embodiment of the present invention. Referring to FIG. 7, a liquid crystal display panel 400 comprises an active device array substrate 410, a color filter substrate 420 and a liquid crystal layer 430. The active device array substrate 410 can be either of the active device array substrates 200 and 300. Related elements are the same to the afore-mentioned embodiments, so a detailed description is omitted. The color filter substrate 420 is disposed in an opposite side of the active device array substrate 410. The liquid crystal layer 430 is disposed between the color filter substrate 420 and the active device array substrate 410.

Similarly, because the active device array substrate 410 has the aforementioned testing device 280 or 380, the cutting process is not required to be performed on the active device array substrate 410 during a process of fabricating the liquid crystal display panel 400. Therefore, the process time and the process cost can be reduced.

In summary, the active device array substrate of the present invention has at least the following advantages:

(1) The testing device can be directly disposed in the narrow-edge region; however, the testing device of the conventional thin film transistor liquid crystal display can only be disposed in the opposite side of the driving circuit. Therefore, according to the present invention, the area of the peripheral circuit region of the panel is prevented from increasing, so that the present invention can be utilized in the both-side gate/source driving circuit arragement.

(2) By disposing the switch elements in the testing device, the additional cutting process for cutting off the electrical connection between the testing device and the electrode lines is not required after the inspection is performed on the active device array substrate. Thereby, the process time and the process cost can be reduced.

(3) The switch element is disposed on the switch lines separated from the electrode lines. Thereby, when transmitting the signal in the display state, the switched-off switch element does not obstruct the signal transmitting in the electrode lines.

(4) By using the shorting bars, the diodes or connecting the panel detecting pads with the same driving signal to one another, the active device array substrate or the liquid crystal display panel is effectively prevented from being damaged by the ESD.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. An active device array substrate having a display region and a peripheral circuit region outside the display region, wherein the peripheral circuit region has a terminal region and a narrow-edge region between the terminal region and the display region, the active device array substrate comprising:
a pixel array, disposed in the display region;
a plurality of electrode lines, disposed in the peripheral circuit region and electrically connected with the pixel array; and
a testing device, disposed in the narrow-edge region for inspecting the active device array substrate.

2. The active device array substrate according to claim 1, wherein the testing device comprises:
a plurality of testing lines, perpendicular to the electrode lines;
a plurality of switch lines, parallel to the electrode lines, each of the switch lines being disposed between two adjacent electrode lines;
a plurality of switch elements, the switch elements being respectively disposed on each of the switch lines, each of the testing lines being electrically connected with each of the electrode lines through each of the switch elements, and an electrode connection point being disposed between each of the electrode lines and each of the testing lines; and
a testing switch line, electrically connected with the switch lines to switch on/off the switch elements.

3. The active device array substrate according to claim 2, wherein the electrode connection point comprises a contact window, and thereby the testing line is electrically connected with the corresponding electrode line through the contact window.

4. The active device array substrate according to claim 2, wherein the switch element comprises at least one thin film transistor (TFT).

5. The active device array substrate according to claim 4, wherein the thin film transistor comprises a gate, a first source/drain and a second source/drain, the gate being electrically connected with the corresponding switch line, the first source/drain being electrically connected with the corresponding electrode line, and the second source/drain being electrically connected with the corresponding testing line.

6. The active device array substrate according to claim 2, wherein the switch element comprises a thin film transistor and a diode.

7. The active device array substrate according to claim 6, wherein the diode is electrically connected between the testing line and the switch line.

8. The active device array substrate according to claim 2, further comprising at least one shorting bar disposed in the peripheral circuit region, the shorting bar being electrically connected with the testing lines.

9. The active device array substrate according to claim 2, wherein the electrode lines comprises scan lines.

10. The active device array substrate according to claim 2, wherein the electrode lines comprises data lines.

11. The active device array substrate according to claim 1, further comprising at least one driver pad connected with the electrode lines, the driver pad being suitable for transmitting a driving signal provided by a driving circuit.

12. The active device array substrate according to claim 11, further comprising at least one panel detecting pad disposed besides the corresponding driver pad, wherein the panel detecting pads with the same driving signal are electrically connected together.

13. A liquid crystal display panel, comprising:
an active device array substrate having a display region and a peripheral circuit region outside the display region, wherein the peripheral circuit region has a terminal region and a narrow-edge region disposed between the terminal region and the display region, the active device array substrate comprising:
a pixel array, disposed in the display region;
a plurality of electrode lines, disposed in the peripheral circuit region and electrically connected with the pixel array;
a testing device, disposed in the narrow-edge region for inspecting the active device array substrate;
A color filter substrate, disposed in an opposite side of the active device array substrate; and
a liquid crystal layer, disposed between the color filter substrate and the active device array substrate.

14. The liquid crystal display panel according to claim 13, wherein the testing device further comprises:
a plurality of testing lines, perpendicular to the electrode lines, the testing lines being electrically connected with the electrode lines respectively;
a plurality of switch lines, parallel to the electrode lines, each of the switch lines being disposed between two adjacent electrode lines;
a plurality of switch elements, the switch elements being respectively disposed on each of the switch lines, each of the testing lines being electrically connected with each of the electrode lines through each of the switch elements, and an electrode connection point being disposed between each of the electrode lines and each of the testing lines; and
a testing switch line, electrically connected with the switch lines to switch on/off the switch elements.

15. The liquid crystal display panel according to claim 14, wherein the electrode connection point comprises a contact window, and thereby the testing line is electrically connected with the corresponding electrode line through the contact window.

16. The liquid crystal display panel according to claim 14, wherein the switch element comprises at least one thin film transistor.

17. The liquid crystal display panel according to claim 16, wherein the thin film transistor comprises a gate, a first source/drain and a second source/drain, the gate being electrically connected with the corresponding switch line, the first source/drain being electrically connected with the corresponding electrode line, and the second source/drain being electrically connected with the corresponding testing line.

18. The liquid crystal display panel according to claim 14, wherein the switch element comprises a thin film transistor and a diode.

19. The liquid crystal display panel according to claim 18, wherein the diode is electrically connected between the testing line and the switch line.

20. The liquid crystal display panel according to claim 14, further comprising at least one shorting bar disposed in the peripheral circuit region, the shorting bar being electrically connected with the testing lines.

21. The liquid crystal display panel according to claim 14, wherein the electrode lines comprise scan lines.

22. The liquid crystal display panel according to claim 14, wherein the electrode lines comprise data lines.

23. The liquid crystal display panel according to claim 13, wherein the active device array substrate further comprises at least one driver pad connected with the electrode lines, the driver pad being suitable for transmitting a driving signal provided by a driving circuit.

24. The liquid crystal display panel according to claim 23, further comprising at least one panel detecting pad disposed besides the corresponding driver pad, wherein the panel detecting pads with the same driving signal are electrically connected together.
